(19) United States
(12) Patent Application Publication
(10) Pub. No.: US 2016/0148834 A1
(43) Pub. Date: May 26, 2016

(54) SOI WAFER FABRICATION METHOD AND SOI WAFER

(71) Applicant: Toyota Jidosha Kabushiki Kaisha, Toyota-shi Aichi-ken (JP)

(72) Inventor: Tetsuya Yamada, Seto-shi (JP)

(21) Appl. No.: 14/922,692

(22) Filed: Oct. 26, 2015

(30) Foreign Application Priority Data
Nov. 26, 2014 (JP) 2014-238699

(51) Int. Cl. H01L 21/762; H01L 29/06; H01L 29/167; H01L 21/02

(52) U.S. Cl. CPC H01L 21/76267; H01L 21/76281; H01L 21/02362; H01L 29/0649; H01L 29/167

(57) ABSTRACT

An SOI wafer fabrication method includes a second process for forming an oxide layer by oxidizing a lamination surface of a support-substrate-forming wafer, third and fourth processes for forming a dopant-containing diffusion layer on a lamination surface of an active-layer-forming wafer and an oxide layer that is provided in contact with the diffusion layer and is capable of preventing the dopant from diffusing, and a fifth process for laminating the support-substrate-forming wafer and the active-layer-forming wafer at the lamination surfaces thereof and applying heat treatment to the laminated wafers.

### PRIORITY INFORMATION

This application claims priority to Japanese Patent Application No. 2014-238699 filed on Nov. 26, 2014, which is incorporated herein by reference in its entirety.

### BACKGROUND OF THE INVENTION

1. Field of the Invention

The present invention relates to fabrication of an SOI wafer based on a laminating method and also relates to an SOI wafer.

2. Description of the Related Art

A Silicon on Insulator (SOI) wafer is recently available for a semiconductor electronic device, such as a high-voltage element or a highly-integrated element. The SOI wafer has a three-layer structure including an active layer that is provided on a surface of a semiconductor substrate and serves as a device manufacture area and an embedded insulating layer, such as an oxide layer, which is provided beneath the active layer extending in the depth direction of the substrate.

A conventionally known SOI wafer fabrication method includes forming an oxide layer on a surface of at least one of a silicon single-crystal wafer serving as a support substrate and a silicon single-crystal wafer including a diffusion layer; laminating these wafers; uniting the laminated wafers through heat treatment; and obtaining an SOI wafer by thinning the silicon single-crystal wafer including the diffusion layer.

However, in a case where the SOI wafer fabrication method includes formation of an embedded oxide film layer, if a diffusion layer capable of suppressing “gettering” or growth of a depletion layer is provided in a shallow region that is adjacent to an interface of the embedded oxide film layer, impurities of the diffusion layer unnecessarily diffuse during a high-temperature heat treatment process in a fabrication operation. For example, if the active layer of the SOI wafer has a film thickness equal to or greater than 10 μm, the diffusion of the impurities occurring during the heat treatment in the laminating operation does not cause any serious problem. However, if the film thickness of the active layer is less than 10 μm, the diffusion of the impurities into the active layer has an adverse influence on electrical characteristics of a device element. More specifically, unevenness in properties (e.g., increase of leakage current occurring at a junction) will occur and reliability will deteriorate.

### SUMMARY OF THE INVENTION

According to an aspect of the present invention, an SOI wafer fabrication method includes a first process for forming an oxide layer by oxidizing a lamination surface of a support-substrate-forming wafer, a second process for forming a dopant-containing diffusion layer on a lamination surface of an active-layer-forming wafer and a diffusion prevention layer that is provided in contact with the diffusion layer and is capable of preventing diffusion of the dopant, and a third process for laminating the support-substrate-forming wafer and the active-layer-forming wafer at the lamination surfaces thereof and applying heat treatment to the laminated wafers.

According to another aspect of the present invention, an SOI wafer includes a semiconductor wafer serving as a support substrate, an embedded oxide layer formed on the semiconductor wafer, and an active layer formed on the embedded oxide layer. The active layer includes a dopant-containing diffusion layer provided adjacent to the embedded oxide layer. A film thickness of the diffusion layer in a region from an interface adjoining the embedded oxide layer to a position where a dopant concentration becomes 1/10 of a maximum value of the dopant concentration is equal to or less than 1 μm.

### BRIEF DESCRIPTION OF THE DRAWINGS

FIG. 1 is a flowchart illustrating an SOI wafer fabrication method according to a first embodiment.

FIG. 2 illustrates a diffusion layer provided in an active layer of the SOI wafer.

FIG. 3 is a flowchart illustrating an SOI wafer fabrication method according to a second embodiment.

FIG. 4 is a flowchart illustrating an SOI wafer fabrication method according to a modification.

### DESCRIPTION OF THE PREFERRED EMBODIMENTS

### First Embodiment

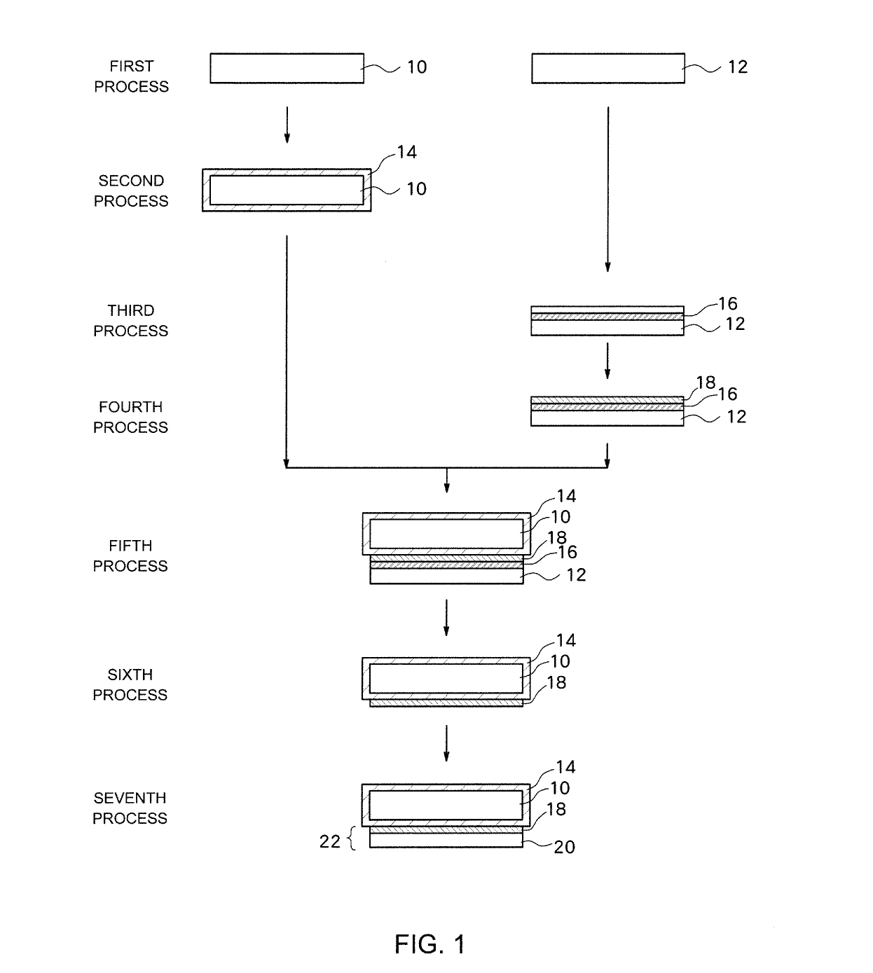

FIG. 1 is a flowchart illustrating a method for fabricating an SOI wafer according to the first embodiment. Hereinafter, the SOI wafer fabrication method according to the first embodiment will be described in detail below with reference to FIG. 1.

The SOI wafer fabrication method includes a first process for preparing a support-substrate-forming wafer 10 and an active-layer-forming wafer 12. The support-substrate-forming wafer 10 is a semiconductor wafer that supports an active layer of an SOI wafer. The active-layer-forming wafer 12 is a semiconductor wafer that can serve as the active layer in a state where the active-layer-forming wafer 12 is laminated with the support-substrate-forming wafer 10. In the present embodiment, the support-substrate-forming wafer 10 and the active-layer-forming wafer 12 are silicon semiconductor wafers.

The SOI wafer fabrication method includes a second process for forming an oxide layer 14 on a surface of the support-substrate-forming wafer 10. The oxide layer 14 is a layer that can serve as an embedded oxide layer (i.e., a BOX oxide layer) of the SOI wafer. As mentioned in detail below, at least part of the oxide layer 14 is formed on a lamination surface when the support-substrate-forming wafer 10 and the active-layer-forming wafer 12 are laminated together. For example, a thermal oxidation method or a deposition method can be employed to form the oxide layer 14. It is desired that the film thickness of the oxide layer 14 is equal to or greater than 1 μm, to assure essential properties required for the embedded oxide layer (i.e., the BOX oxide layer) of the SOI wafer.

The SOI wafer fabrication method includes a third process for forming an oxide layer 16 in the active-layer-forming wafer 12. The oxide layer 16 is usable for separating the active-layer-forming wafer 12 from the SOI wafer, as mentioned below. Further, the oxide layer 16 functions as a diffusion prevention layer capable of suppressing the dopant from diffusing in a diffusion layer to be formed in the active layer of the SOI wafer. A method employable to form the oxide layer 16 is, for example, Separation by IMplantation of OXygen (SIMOX) based on ion implantation of oxygen atoms into the active-layer-forming wafer 12. The ion implantation can be performed with implantation energy being set at an appropriate level, by which a non-oxidized area serving as a diffusion layer remains on the lamination surface of the active-layer-forming wafer 12. Further, a general laminating method can be employed to form the oxide layer 16.

The SOI wafer fabrication method includes a fourth process for forming a diffusion layer 18 in the active-layer-forming wafer 12. The diffusion layer 18 can be formed by introducing the dopant into a region positioned on the surface side of the embedded oxide layer 16, which is far from the lamination surface of the active-layer-forming wafer 12. For example, the film thickness of the diffusion layer 18 is set to be approximately in a range of not less than 0.1 μm and not greater than 0.3 μm. Further, regarding the dopant to be introduced into the diffusion layer 18 in a case where the active-layer-forming wafer 12 is a silicon semiconductor wafer, phosphorus (P) and arsenic (As) are selectable as n-type dopant and boron (B), aluminum (Al), and antimony (Sb) as p-type dopant.

The diffusion layer 18 can be formed by adding the dopant according to an ion implantation method. It is desired that the amount of the dopant to be introduced is differentiated in consideration of the purpose of use of the diffusion layer 18. In a case where the diffusion layer 18 is provided as a general highly-concentrated dopant layer for the purpose of field relaxation, it is desired that the concentration of ions in the dopant, such as phosphorus (P), arsenic (As), boron (B), and antimony (Sb), in ion implantation is within a range of not less than 10¹²/cm² and not greater than 10¹²/cm². On the other hand, in a case where the diffusion layer 18 is formed for the purpose of “gettering,” it is desired that the concentration of ions in the dopant, such as arsenic (As) and antimony (Sb), in ion implantation is within a range of not less than 10¹⁵/cm² and not greater than 10¹⁶/cm². Gettering is a phenomenon by which metallic impurities contained in the wafer are collected in the diffusion layer 18. Positively using the gettering phenomenon is useful to prevent a device element formed in the active layer of the SOI wafer from being adversely influenced by metallic impurities. The amount of the dopant to be introduced into the diffusion layer 18 is not limited to the above-mentioned example and can be appropriately changed according to the purpose of use. Further, although the ion implantation energy is not limited to the above-mentioned example, it is desired that the ion implantation energy is within a range of not less than 40 keV and not greater than 100 keV. As another method, the photolithographic technique or the like is available to locally form the diffusion layer 18 in the fourth process.

The SOI wafer fabrication method includes a fifth process for laminating the support-substrate-forming wafer 10 and the active-layer-forming wafer 12 together. More specifically, in the fifth process, the lamination surface of the support-substrate-forming wafer 10 is brought into contact with the lamination surface of the active-layer-forming wafer 12 in a mutually opposed relationship. The support-substrate-forming wafer 10 and the active-layer-forming wafer 12 are laminated together through a heat treatment, which is performed under application of an appropriate pressure. It is desired that the heating treatment is performed within a temperature range of not less than 1100° C. and not greater than 1200° C. during a treatment time not shorter than one hour and not longer than three hours.

Through the heat treatment performed in the fifth process, the dopant diffuses in the diffusion layer 18 that adjoins the oxide layer 16. The dopant concentration in the diffusion layer 18 can be uniform. In this case, a diffusion coefficient of the dopant contained in the oxide layer 16 is smaller than a diffusion coefficient of the dopant contained in the diffusion layer 18 by approximately 2 to 3 orders of magnitude. Therefore, the oxide layer 16 can serve as a dopant diffusion mask. The diffusion of the dopant substantially occurs only in the diffusion layer 18. For example, in a case where the oxide layer 16 is not provided, the dopant diffuses to the extent of approximately 2 μm to 4 μm. On the other hand, in a case where the oxide layer 16 is provided, the diffusion distance is shortened to approximately 0.1 μm to 0.5 μm. In other words, the dopant remains in the diffusion layer 18. Accordingly, it is feasible to cause the dopant concentration to change steeply at the interface between the oxide layer 16 and the diffusion layer 18.

The SOI wafer fabrication method includes a sixth process for removing the active-layer-forming wafer 12 and the oxide layer 16 while leaving the diffusion layer 18. A chemical mechanical polishing (CMP) method can be employed to remove the active-layer-forming wafer 12. Further, a wet etching method or a dry etching method can be employed to remove the residual silicon on the oxide layer 16 together with the oxide layer 16. Through the above-mentioned process, only the diffusion layer 18 is left on the oxide layer 14 formed on the surface of the support-substrate-forming wafer 10.

The SOI wafer fabrication method includes a seventh process for forming an epitaxial layer 20 on the diffusion layer 18. The epitaxial layer 20 can be formed on the diffusion layer 18 by supplying a silicon-containing source gas, such as trichlorosilane (HSiCl₃) or silane (SiH₄), to the surface of the diffusion layer 18 while heating the support-substrate-forming wafer 10, on which the diffusion layer 18 remains, within a temperature range of not less than 1100° C. and not greater than 1200° C. If necessary, hydrogen (H₂) is available to dilute the source gas. Further, mixing a dopant-containing gas with the source gas may be useful.

Although the film thickness of the epitaxial layer 20 is not limited to a specific value, it is desired that an active layer 22 has a sufficient film thickness. For example, it is desired that the film thickness of the epitaxial layer 20 is equal to or greater than 3 μm. The diffusion layer 18 and the epitaxial layer 20 cooperatively serve as the active layer 22 of the SOI wafer.

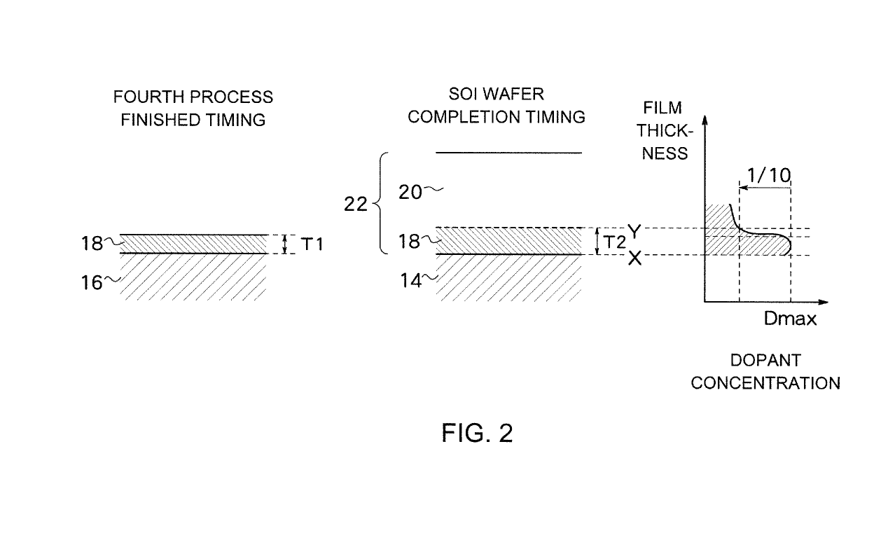

A period of time required to form the epitaxial layer 20 is several minutes. Therefore, the diffusion of the dopant from the diffusion layer 18 to the epitaxial layer 20 can be substantially suppressed without any adverse influence. Accordingly, as illustrated in FIG. 2, in a case where the film thickness T1 of the diffusion layer 18 formed in the fourth process is within a range of not less than 0.1 μm and not greater than 0.3 μm, even if the diffusion of the dopant occurring during the heat treatment in the fifth process is taken into consideration, a film thickness T2 from an interface X; i.e., the boundary between the oxide layer 14 (i.e. the embedded oxide layer) and the diffusion layer 18, to a position Y, at which the dopant concentration becomes 1/10 of a maximum value Dmax of the dopant concentration of the diffusion layer 18, can be suppressed to 0.6 μm to 1.0 μm. More specifically, the substantial thickness of the diffusion layer 18 is equal to or less than 1 μm, when it is measured from the interface X between the oxide layer 14 and the diffusion layer 18.

Secondary ion mass spectrometry (SIMS) can be employed to measure a change in the depth direction with respect to the dopant concentration of the SOI wafer. More specifically, it is feasible to measure a distribution of the dopant concentration in the depth direction of the SOI wafer by performing SIMS measurement while scraping an SOI wafer sample in the depth direction.

As mentioned above, according to the SOI wafer fabrication method according to the present embodiment, it is feasible to substantially limit the diffusion of the dopant in the diffusion layer 18 because of the presence of the oxide layer 16, when the dopant diffuses in the active layer forming wafer 12 during the heat treatment in the wafer laminating operation. More specifically, it is feasible to suppress the impurities included in the diffusion layer 18 from unnecessarily diffusing during a high-temperature heat treatment in the SOI wafer fabrication operation. Accordingly, it is feasible to prevent electrical characteristics of a device element formed in the active layer 22 from deteriorating because of the diffusion of the dopant. In particular, if the film thickness of the active layer 22 provided in the SOI wafer is less than 10 μm, the electrical characteristics of a device element formed in the active layer 22 will be greatly influenced by the diffusion of the dopant from the diffusion layer 18. Therefore, the present embodiment brings remarkable effects in suppressing the adverse influence on the device element and can prevent deterioration in the electrical characteristics of a device element. Further, in the fourth process for forming the diffusion layer 18, it is useful to locally form the diffusion layer 18 according to the photolithographic technique in such a way as to suppress local diffusion of the dopant.

### Second Embodiment

According to the above-mentioned first embodiment, the provision of the oxide layer 16 intends to suppress the dopant from diffusing in a film thickness direction in the active layer 22 of the SOI wafer. The second embodiment is different from the first embodiment in that a trench-shaped embedded oxide layer is formed in a partial area of the diffusion layer 18, on the lamination surface of the active-layer-forming wafer 12, to suppress the dopant from diffusing in the horizontal direction (i.e., the in-plane direction of the wafer).

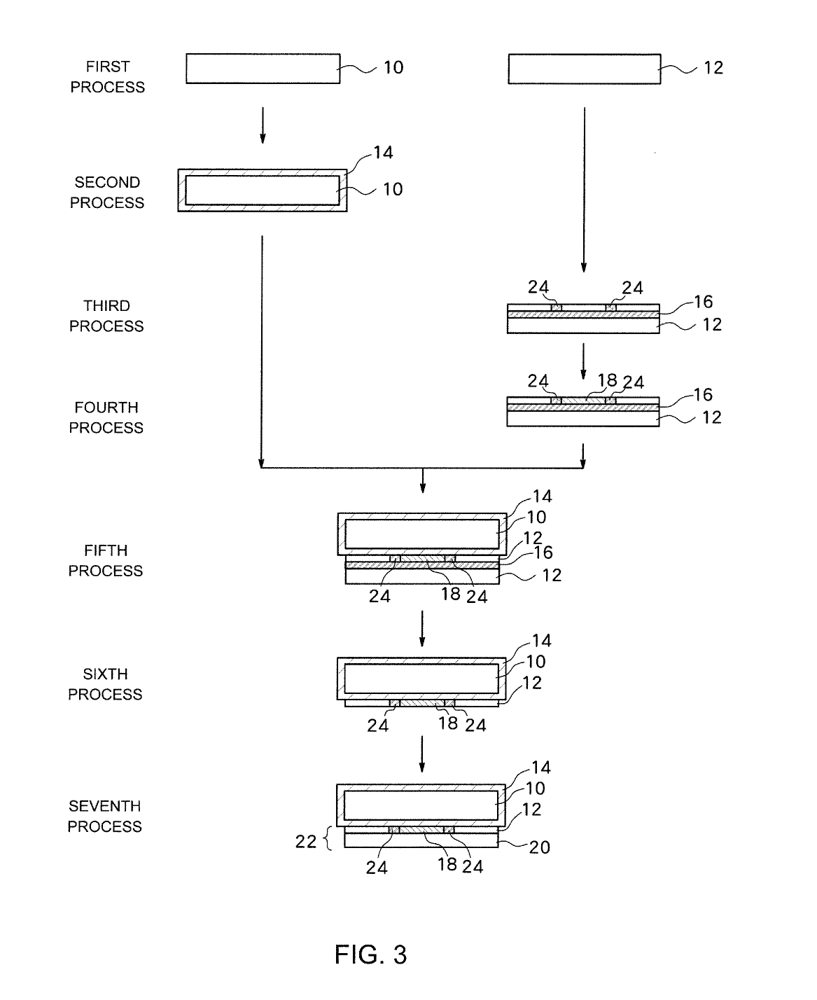

FIG. 3 is a flowchart illustrating a method for fabricating an SOI wafer according to the second embodiment. Hereinafter, the SOI wafer fabrication method according to the second embodiment will be described in detail below with reference to FIG. 3. When processing content is similar to that already described in relation to the first embodiment, redundant description thereof will be omitted.

The SOI wafer fabrication method includes a third process for forming the oxide layer 16 and an oxide layer 24 having a trenched shape in the active-layer-forming wafer 12. A method for forming the oxide layer 16 is similar to that described in relation to the first embodiment. After the formation of the oxide layer 16 is completed, etching according to the photolithographic technique is applied to a partial area of a silicon layer, to leave the trenched oxide layer 24, in the area serving as the diffusion layer 18. Then, the oxide layer 24 is embedded in the above-mentioned area, and a surface of the oxide layer 24 is flattened through a polishing operation according to the chemical mechanical polishing (CMP) method.

The SOI wafer fabrication method includes a fourth process for forming the diffusion layer 18 in the active-layer-forming wafer 12. The diffusion layer 18 can be formed by introducing the dopant into an area surrounded by the oxide layer 24 by using the photolithographic technique, in the surface side region far from the embedded oxide layer 16 provided adjacent to the lamination surface of the active-layer-forming wafer 12. Accordingly, the diffusion layer 18 can be formed as a trenched region separated by the oxide layer 24.

The SOI wafer fabrication method includes fifth to seventh processes that are similar to those described in the first embodiment. Thus, there can be formed an SOI wafer including an active layer (including the epitaxial layer 20 and the diffusion layer 18), the oxide layer 14, and the support-substrate-forming wafer 10, which are laminated together.

In the present embodiment, the oxide layer 16 and the oxide layer 24 cooperatively function as a dopant diffusion mask. The dopant introduced in the diffusion layer 18 diffuses exclusively in the region surrounded by the oxide layer 16 and the oxide layer 24, through the heat treatment performed in the laminating process (i.e., the fifth process). As mentioned above, suppressing the diffusion of the dopant not only in the depth direction but also in the plane direction (i.e., in the horizontal direction) of the SOI wafer is useful to locally form the diffusion layer 18 that has a higher dopant concentration at a position adjacent to the oxide layer 16 serving as the embedded oxide layer of the SOI wafer.

Accordingly, in a case where an embedded diffusion layer is formed in a partial area on the surface of the SOI wafer, it is feasible to prevent the diffusion of the dopant from occurring in the horizontal direction during the heat treatment performed in the laminating operation. Further, it is feasible to shorten the distance between mutually neighboring device elements and reduce a chip area.

In particular, in the formation of a device element in the surface region of the active layer provided in the SOI wafer, it is feasible to shorten a plane distance between a device element that requires the diffusion layer 18 and a device element that does not require the diffusion layer 18. Accordingly, the chip area can be reduced and the degree of integration of elements can be enhanced. In the present embodiment, the provision of the oxide layer 16 intends to suppress the dopant from diffusing in the depth direction. However, the oxide layer 16 can be omitted if it is desired to suppress the diffusion of the dopant only in the plane direction (i.e. the horizontal direction) by the oxide layer 24.

### Modification

In the second embodiment, the formation of the diffusion layer 18 is limited to only one spot area on the surface of the active-layer-forming wafer 12. However, the formation of the diffusion layer 18 is not limited to the above-mentioned example. For example, it is useful to form the diffusion layer 18 at each of a plurality of spot areas.

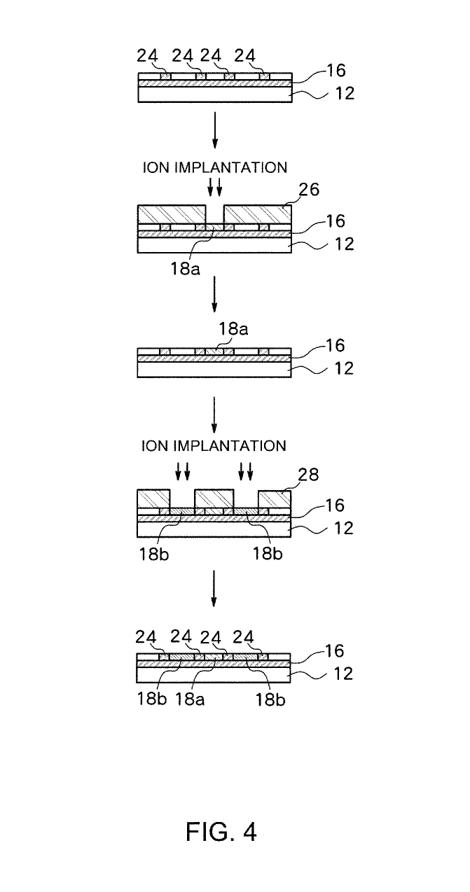

More specifically, in the above-mentioned fourth process according to the second embodiment, it is feasible to form a plurality of diffusion layers 18 (see 18a and 18b) on the lamination surface of the active-layer-forming wafer 12 by repetitively applying the photolithographic technique two times or more, as illustrated in FIG. 4. According to the example illustrated in FIG. 4, a resist layer 26 is formed through a first photolithographic operation. Then, a diffusion layer 18a is formed at a central portion of the wafer through ion implantation performed with a mask constituted by the resist layer 26. Subsequently, the resist layer 26 is removed. Then, a resist layer 28 is newly formed through a second photolithographic operation. Subsequently, a diffusion layer 18b is formed on both sides of the diffusion layer 18a through ion implantation performed with a mask constituted by the resist layer 28.

In this case, differentiating ion implantation conditions (e.g., ion implantation amount and ion implantation energy) applied to the diffusion layer 18a from ion implantation conditions applied to the diffusion layer 18b is useful for forming the plurality of diffusion layers 18 composed of the diffusion layer 18a and the diffusion layer 18b that are different in dopant amount and dopant distribution.

Further, as the oxide layer 16 formed on the active layer forming wafer 12 is available as an alignment mark for forming the plurality of diffusion layers 18, it is feasible to omit an alignment mark forming process for forming the diffusion layer 18. Further, it is feasible to locally form the plurality of diffusion layers 18 by using the oxide layer 16 (i.e., the alignment mark).

According to the modification, it is feasible to locally form the diffusion layer 18 that is suitable for each device element at an area in which the device element is formed, while considering properties of the diffusion layer 18 required for each device element formed in the active layer of the SOI wafer. Therefore, improving the properties of each device element formed on the SOI wafer is feasible.

As apparent from some embodiments and relevant modification, the present invention can be applied to various types of SOI wafers and can improve the properties of each device element formed on the SOI wafer.

What is claimed is:

1. An SOI wafer fabrication method, comprising:
a first process for forming an oxide layer by oxidizing a lamination surface of a support-substrate-forming wafer;
a second process for forming a dopant-containing diffusion layer on a lamination surface of an active-layer-forming wafer and a diffusion prevention layer that is provided in contact with the diffusion layer and is capable of preventing the dopant from diffusing; and
a third process for laminating the support-substrate-forming wafer and the active-layer-forming wafer at the lamination surfaces thereof and applying heat treatment to the laminated wafers.

2. The SOI wafer fabrication method according to claim 1, wherein at least a part of the diffusion prevention layer is formed at a position deeper than the diffusion layer in a film thickness direction, when seen from the lamination surface of the active-layer-forming wafer.

3. The SOI wafer fabrication method according to claim 1, wherein the diffusion layer is formed in a partial area on the lamination surface of the active-layer-forming wafer, and the diffusion prevention layer is formed in a circumferential area of the diffusion layer.

4. The SOI wafer fabrication method according to claim 2, wherein the diffusion layer is formed in a partial area on the lamination surface of the active-layer-forming wafer, and the diffusion prevention layer is formed in a circumferential area of the diffusion layer.

5. The SOI wafer fabrication method according to claim 1, wherein the diffusion prevention layer is a silicon oxide layer having a film thickness equal to or greater than 0.1 μm.

6. The SOI wafer fabrication method according to claim 2, wherein the diffusion prevention layer is a silicon oxide layer having a film thickness equal to or greater than 0.1 μm.

7. The SOI wafer fabrication method according to claim 3, wherein the diffusion prevention layer is a silicon oxide layer having a film thickness equal to or greater than 0.1 μm.

8. An SOI wafer, comprising:
a semiconductor wafer serving as a support substrate;
an embedded oxide layer formed on the semiconductor wafer; and
an active layer formed on the embedded oxide layer,
wherein the active layer includes a dopant-containing diffusion layer provided adjacent to the embedded oxide layer, and a film thickness of the diffusion layer in a region from an interface adjoining the embedded oxide layer to a position where a dopant concentration becomes 1/10 of a maximum value of the dopant concentration is equal to or less than 1 μm.

9. The SOI wafer according to claim 8, wherein a film thickness of the active layer is less than 10 μm.
